(19) United States
(12) Patent Application Publication
(10) Pub. No.: US 2019/0064223 A1
(43) Pub. Date: Feb. 28, 2019

(54) Method and Apparatus for Detecting the Start of an Event in the Presence of Noise

(71) Applicant: Keysight Technologies, Inc., Minneapolis, MN (US)

(72) Inventor: Robert Kincaid, Half Moon Bay, CA (US)

(73) Assignee: Keysight Technologies, Inc., Minneapolis, MN (US)

(21) Appl. No.: 15/687,347

(22) Filed: Aug. 25, 2017

(51) Int. Cl. G01R 13/02; G06F 7/02

(52) U.S. Cl. CPC G01R 13/029; G01R 13/0254; G06F 7/02

(57) ABSTRACT

A method for operating a data processing system to detect the presence of an event in a data stream includes an ordered sequence of digital values, xᵢ, for i=1 to N_{d} is disclosed. The method includes causing the data processing system to determine a base value for a statistical parameter of the data digital values within a training window. Then for each xᵢ in a region of interest in the ordered sequence of digital values, the data processing system determines a sliding value for the statistical parameter corresponding to that xᵢ by measuring the statistical parameter of the xᵢ within a sliding window containing the xᵢ and which is different for each xᵢ. The data processing system compares the sliding value to the base value for each xᵢ in the region of interest to determine if the xᵢ is part of an event.

### BACKGROUND

Modern measurement instruments often generate a stream of digital measurement values that include a significant level of noise. In many applications of interest, a system that consumes such a digital stream is faced with the problem of determining when an event starts. Determining when an event occurs in the presence of noise presents significant challenges. For example, a digital oscilloscope measures the amplitude of a signal as a function of time and displays a portion of the observed signal as a graph of signal amplitude as a function of time. Modern digital oscilloscopes can measure a signal at a rate of close to 100 Gigasamples/sec in each of a plurality of measurement channels. The signal is typically digitized using a bank of sample and hold circuits that sample the signal in successive time slots. Each sample and hold circuit feeds a high-speed analog-to-digital converter (ADC) that stores its output in a high-speed memory bank that is assigned to that ADC.

Only a small fraction of this recorded data can be displayed at a time, and hence, some form of trigger is needed to define the beginning of the measurements of interest that are to be displayed. Once the trigger event is detected, the system ceases accumulating new data once the buffer is full, and hence, a false trigger can result in dead time during which the real event of interest occurs. Consider a leading-edge trigger in which the trigger event is the signal increasing above some predetermined level. If the level is too low, there will be many false triggers caused by noise. If the level is too high, the beginning of the trigger event may be lost, or the trigger event may be missed because the signal increased above the noise level significantly, but not to the level specified by the trigger.

### SUMMARY

The present invention includes a method for operating a data processing system to detect the presence of an event in a data stream includes an ordered sequence of digital values, xᵢ, for i=1 to N_{d}. The method includes causing the data processing system to determine a base value for a statistical parameter of the data digital values within a training window. Then for each xᵢ in a region of interest in the ordered sequence of digital values, the data processing system determines a sliding value for the statistical parameter corresponding to that xᵢ by measuring the statistical parameter of the xᵢ within a sliding window containing the xᵢ and which is different for each xᵢ. The data processing system compares the sliding value to the base value for each xᵢ in the region of interest to determine if the xᵢ is part of an event.

In one aspect of the invention, the data stream includes a signal that is corrupted by noise characterized by a noise spectrum and the statistical parameter includes a measure of the noise spectrum.

In another aspect, the statistical parameter includes a probability that one of the digital values will be an outlier.

In another aspect, the statistical parameter includes a standard deviation of the digital values.

In another aspect, the training window includes the sliding window.

In another aspect, the training window does not include the sliding window.

In another aspect, the digital values are scalar values having only two states, digital values having one of the two states being defined as outliers.

In another aspect, each of the digital values is a vector having a plurality of components.

In another aspect, the training window includes the previous M samples from the data stream prior to the xᵢ corresponding to the sliding window, the training window is at least four times larger than the sliding window, the sliding window moving with the xᵢ.

The present invention also includes an analyzer that measures a signal in a region of a potential event of interest. The analyzer includes a port for receiving the signal and converting the signal to an ordered sequence of digital values, xᵢ, for i=1 to N_{d}, and a trigger circuit that determines a sliding value for a statistical parameter for each of the xᵢ in the region based on a sliding window containing that xᵢ and moving with each xᵢ, the triggering signal generating an event of interest signal if the sliding value is greater than a base value for the statistical parameter determined from an analysis of the xᵢ in a training window.

In another aspect, the signal is corrupted by noise characterized by a noise spectrum, the statistical parameter includes a measure of the noise spectrum.

In another aspect, the statistical parameter includes a probability that one of the digital values will be an outlier.

In another aspect, the statistical parameter includes a standard deviation of the digital values within the sliding window.

In another aspect, the training window includes the sliding window.

The present invention also includes a method for operating a data processing system to monitor a testing system that makes a measurement on a series of devices under test for failures of the testing system. The method includes generating an ordered digital sequence of digital values, xᵢ, for i=1 to N_{d}, from a measurement output of the testing system, the output measuring a property of each device under test, and causing the data processing system to determine a base value for a statistical parameter of the data digital values within a training window For each xᵢ in a region of interest in the ordered sequence of digital values, the data processing system determines a sliding value for the statistical parameter corresponding to that xᵢ by measuring the statistical parameter of the xᵢ within a sliding window containing the xᵢ and which is different for each xᵢ and comparing the sliding value to the base value for each xᵢ in the region of interest to determine if the xᵢ is part of an event.

In another aspect, the statistical parameter includes a probability that one of the digital values will be an outlier.

In another aspect, the digital values are scalar values having only two states, digital values having one of the two states being defined as outliers.

### BRIEF DESCRIPTION OF THE DRAWINGS

FIGS. 1A and 1B illustrate the counting function scheme.

FIG. 2 illustrates a simple embodiment of an oscilloscope in which the present invention can be used to perform triggering.

FIG. 3A is a plot of a noisy data stream in which an event starts around sample 500.

FIG. 3B is a plot of a counting function that counts the number of outliers in a window of size 151 samples.

FIG. 4 illustrates the counting function that is obtained if only the first quarter of the samples in FIG. 3A is used to compute the statistics on which the outlier cut-off is based.

### DETAILED DESCRIPTION

Consider a data stream generated by an instrument. The data stream may be the result of monitoring some physical signal such as a voltage or current in a circuit or may be the result of monitoring the output from a test instrument that performs tests on devices on a production line or the like. It is assumed that these data streams are subject to a significant amount of noise. For the purposes of this discussion, noise will be defined to be random fluctuations in a signal about some average value. The random fluctuations can be in the amplitude of the values or in the timing of the values. For example, a binary signal having randomly occurring ones has random fluctuations in the timing of the values that result in a signal that has random fluctuations in the average amplitude.

Noise is typically measured by performing a statistical analysis of a large number of samples from the data stream to measure a statistical parameter characterizing the noise. For the purposes of this discussion, a statistical parameter is any parameter derived from the average value of a function of the absolute difference between the individual signal values within a window and an average of the signal values. The average value can be determined from the values in the window or in a separate training window. Examples of such statistical parameters include a function of the standard deviation of the data stream values within the window and a function of the average value of the absolute difference of the individual data values and the average value.

The number of outliers within the window or a function thereof is another example of a statistical parameter. For the purposes of this discussion, an outlier is defined to be a signal value that differs from the average signal value by more than a predetermined threshold value. Consider a constant signal is digitized to provide the data stream in which the signal is corrupted by noise having a Gaussian distribution, the number of outliers in a window is a measure of the standard deviation of the signal about the underlying signal value. In this case, the threshold value can be determined from the desired fraction of the signal values that is to be defined as outliers from the standard deviation of the noise.

The outlier threshold value can be a predetermined level or it can be defined by performing a statistical analysis on the measurements within a first window, referred to as a training window, in the data stream to determine a level that selects some predetermined fraction of the measurements as outliers. For example, if the data values are corrupted by noise having a Gaussian distribution, the samples in the training window can be analyzed to determine the mean and standard deviation of the values about the mean. The threshold value can then be set by some predetermined number of standard deviations from the mean. If the fluctuations in the data values are not distributed according to a known statistical distribution, the threshold value can be set by finding the level that results in a predetermined percentage of the data values being defined as outliers by searching different threshold values.

Given an outlier identification threshold, the probability that any particular measurement is an outlier, p, can be determined by counting the outliers in the training window and dividing the number of outliers by the number of samples in the training window.

In embodiments that utilize the number of outliers in a window as the statistical parameter, it is useful to define a function, Co(W,x), that counts the number of outliers in a portion of the data stream within a sliding window, W, that moves along the data stream beginning with a sample that has a fixed relative position to x. For the purpose of this particular type of embodiment, this window will be referred to as the counting window in the following discussion. For example, the window could start at x−Nₛ/2, where Nₛ is the length of the counting window in the samples. In another example, the counting window could start at x. In general, Co(W,x) will fluctuate about the average number of outliers expected in W if there is no underlying event that would change the average value of the entries in data stream. The present invention is based on the observation that if the underlying signal is corrupted by noise and that noise changes significantly within the window, the number of outliers will also increase significantly. In the limit, the Co(W,x) will have a value Nₛ; that is, each point will have deviated by enough to turn that point into an outlier as viewed by the outlier function. By observing the magnitude and shape of Co(W,x), the existence of an underlying event and some information about the nature of that event can be deduced.

For the purposes of the present discussion, an event is defined to be a change in the underlying signal that warrants investigation by a user or the data processing system. The event typically starts at a particular point in the sequence of digital values. To detect an event, a base value for the statistical parameter being measured must be determined in a region of the data stream that is predominantly event free. This region will be referred to as the training window in the following discussion. The data processing system analyzes the data values in the training window to determine an average value for the signal and a base value for the statistical parameter. In the case of embodiments that count the number of outliers in the sliding window, the average value and a base value count are determined in the training window. The statistical parameter in each sliding window is then compared to that in the training window to determine if an event has occurred. Ideally, the training window is much larger than the sliding window.

In general, the statistical accuracy with which the statistical parameter can be determined will have some uncertainty due to the underlying noise in the training window and in the sliding windows. This statistical uncertainty typically decreases with the number of samples in the window, larger windows having smaller statistical uncertainties. While the contribution to the overall uncertainty can be improved by increasing the size of the training window, assuming that the background remains stable, the size of the sliding window is set by a number of criteria and is not as free as the size of the training window. Since both the base value and sliding window values are subject to noise, it is advantageous to reduce the noise in the value derived from the training window to a level that is small compared to the uncertainty in the sliding window value to distinguish false positive events arising from the statistical variations in the base and sliding window values. In one aspect of the invention, the size of the training window is at least four times that of the sliding window.

The optimum size of the sliding window depends on the duration of the event that is being sought. If the length of the event is short compared to the size of the sliding window, the deviation in the measured statistical parameter will be “diluted” by the portion of the sliding window in which the event is not present. However, if a very small sliding window is utilized, the statistical fluctuation in the statistical parameter being measured will set a limit as to the smallest deviation in the statistical parameter that can be detected with a given degree of confidence that the observed variation is in fact an event of interest, and not merely the result of the statistical fluctuations in the data stream. In one aspect of the invention, a plurality of different length sliding windows are used to test the current point in the data stream. A short event will be more visible in the shorter windows. Hence, by observing which sliding windows detect an event, information about the length of the event can be deduced. For example, if an event changes the data stream over a long period of samples, the event will be seen first in the shorter test windows and then with increased certainty in the longer windows.

The data processing system then determines if each xᵢ in the region of interest is part of an event. In the case of a counting function, an event is defined to be a sub-sequence of the digital values that has an elevated count and that has a probability of being the result of noise that is less than some predetermined probability threshold. The probability threshold will depend on the specific data stream being examined. This determination is made by counting the number of outliers in a moving counting window containing xᵢ. A counting window containing xᵢ is defined to be a sub-sequence of the digital values that contains xᵢ, has a fixed number of contiguous digital values, and maintains a fixed relationship with xᵢ so that the window moves as xᵢ is changed.

In general, an xᵢ is part of an event if the count function differs from the expected number of outliers in the moving window that would be expected from the statistical analysis of the training sample by more than some predetermined event threshold value. The manner in which the event threshold value is determined will be discussed in more detail below. An xᵢ whose count function value is less than the event threshold value but greater than a lower event threshold value may be considered to be part of the event if one of the adjacent xᵢ values is determined to be part of the event.

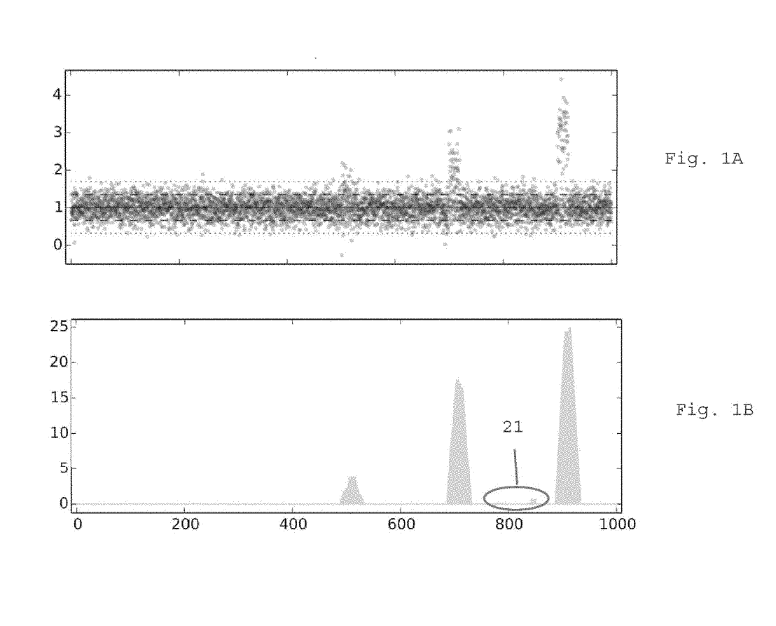

Refer now to FIGS. 1A and 1B, which illustrate the counting function scheme discussed above. FIG. 1A is a plot of a measurement having a mean value of 1 and a significant amount of noise. The vertical axis is the signal value in units of the standard deviation of the noise. FIG. 1B is a plot of Co(W,x) after subtracting the expected number of outliers based on a training sample for a window width of 151 samples and an outlier being defined to be a value greater than two standard deviations from the mean. As can be seen from the drawing, the Co function can be used to easily find both the start and duration of the features corrupted by the noise shown in FIG. 1A.

The optimal size of W will depend on the underlying problem. There is a tradeoff between the sensitivity for detecting small changes in the number of outliers that signal the start of an event and the ability to detect the starting point. If W is large, then Co will be almost constant in areas that do not have an underlying event. However, the resolution of Co for determining the existence of an underlying event that is less than W in duration will be compromised. If W is too small, the fluctuations in Co may mask the beginning of an event or inhibit the ability to detect small changes in the number of outliers.

In one embodiment, the present invention detects an event by measuring changes in the number of outliers between the training window and the counting window. The probability that a measurement value is an outlier depends on the threshold selected during the training phase. If the threshold is varied, then p varies in response. Hence, both p and the counting window size can be varied to alter the sensitivity with which events can be detected.

While the present invention detects changes in the number of outliers between the training window and the counting window, the present invention can be viewed as detecting changes in the probability that a data value is an outlier. The size of the counting window and the p value chosen in the training process determine the minimum change in the p value that can be detected with a given counting window size and starting p value.

The p value observed in the sliding window can be written as p=p₀+dp, where p₀ is the p value measured during the training period for the particular choice of outlier threshold. Since we are interested in the smallest change that can be detected, it will be assumed that dp<<p₀. The difference in the count observed during the counting window and that expected from the training window can then be written as

Co(Ws,x)=p*Nₛ−p₀*Nₛ=dp*Nₛ

Here, the expected number of outliers, p₀*Nₛ has been subtracted from the observed number of outliers, p*Nₛ.

This count is subject to shot noise. The standard deviation of the shot noise is approximately the square root of the count. We assume that dp is small compared to p, and hence, the error in the count due to shot noise has a standard deviation of approximately the square root of p₀*Nₛ. To determine that an observed dp is the result of a change in the underlying signal as opposed to shot noise, Co(Ws,x)>k\sqrt{(pₒ*Nₛ)} where k is a value that determines the degree of certainty that the result is not just the result of noise. Hence, the smallest change in p that can be detected with a reliability of k sigmas is k*\sqrt{(pₒ/Nₛ)}. Accordingly, embodiments are preferred in which the outlier probability is small and Nₛ is large enough to ensure a sufficient number of outliers can be counted in both the presence and absence of trigger events to ensure valid counting statistics. It should be noted, however, that p₀ also determines the difference in the counting function values between the background and an event of interest. The counting function varies between p₀Nₛ in areas without events to a maximum of Nₛ in areas with events for embodiments that utilize the number of outliers as the statistical parameter being measured. Hence, a p₀ of less than 0.5 is preferred in such embodiments.

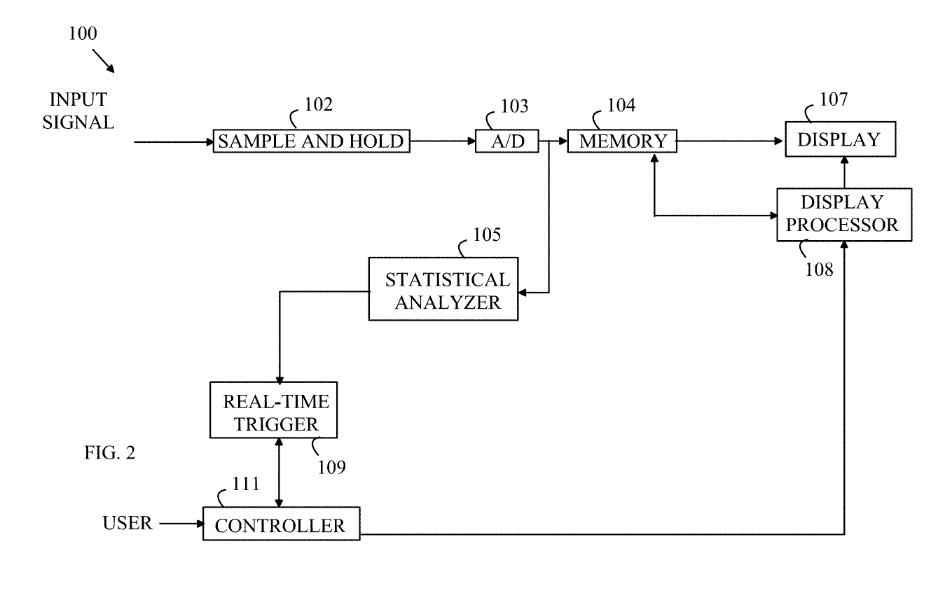

As noted above, the data stream can be scalar or vector in nature. One simple example of a scalar data stream is the input to one channel of an oscilloscope or signal analyzer. Refer now to FIG. 2, which illustrates a simple embodiment of an oscilloscope in which the present invention can be used to perform triggering. Oscilloscope 100 includes a sample and hold circuit 102 which samples an incoming waveform serially. The output of sample and hold circuit 102 is digitized by ADC 103 and the results stored in memory 104. It should be noted that sample and hold circuit 102 can include a bank of sample and hold circuits that serially sample the incoming signal, and ADC 103 and memory 104 can likewise be constructed in banks to provide parallel processing for increasing the sampling rate and/or providing a sampling window that is much shorter than the ADC conversion times. A high-speed oscilloscope can sample 100 Gigasamples per second in each of a plurality of measurement channels. Only a small fraction of this data is typically of interest. Hence, some form of “trigger” is utilized to define the beginning of a region of potential interest in the signal. When the trigger is detected, the instrument records the signal from the trigger to some point in time that depends on the storage capacity of the memory banks. It is advantageous to provide a real-time trigger that can operate at the speed of the incoming data. The present invention can be used to implement such a real-time trigger when the signal being digitized has a significant level of noise to cause an unacceptable level of false triggers.

Oscilloscope 100 utilizes a statistical analyzer 105 according to the present invention to detect the start of an event. The input signal is captured and digitized by sample and hold circuit 102 and ADC 103 to generate a digital sequence that is stored in memory 104. When each new sample is stored, statistical analyzer 105 determines if an event has been detected and displays the portion of the stored digital sequence containing the event on display 107.

Statistical analyzer 105 uses two windows. The first window is a large window that captures the previous N samples and performs a statistical analysis on those samples to determine the average value of the signal and the probability that any given sample is an outlier in the absence of an event. The threshold to be used in determining if a sample is an outlier can be specified by the user through a graphical user interface connected to controller 111. When a trigger event is detected by real-time trigger generator 109, controller 111 causes display processor 108 to display the digital sequence, or some function derived from that sequence. The trigger is typically generated when the number of outliers in the sliding window exceeds some predetermined threshold. The statistical analysis of this training sample can be used to determine the criterion for labeling a sample as an outlier based on a statistical model of the data stream.

For example, the model can assume that the data stream values have a Gaussian distribution and that a sample that differs from the mean by more than a predetermined number of standard deviations is an outlier. In this case, the data processing system would measure the standard deviation of the sample about the mean and set the signal level above or below which a sample would be considered to be an outlier. The data processing system would then use this cut-off to determine the actual probability that a sample is an outlier by counting the number of outliers in the training window using this cutoff and then dividing by the number of samples in the training window.

In another example, the user provides a cut-off for defining an outlier relative to the mean of the samples in the training window and the data processing system computes the probability that any given sample is an outlier with this definition by counting the number of outliers in the training window and dividing by the number of samples in the training window.

In another example, the user provides the desired value of p in the training window, and the computer determines the cut-off value that provides that fraction of the training window samples as outliers.

The probability that a sample is an outlier can then be used to compute the expected number of outliers in a counting window by multiplying the determined probability by the number of samples in the counting window.

In one exemplary embodiment, the statistical analysis is performed on the data stored in memory 104 and is updated as each new data value is received. For example, a circular buffer that has a length equal to the length of the training window and the length of the counting window is used to store the data values as the values arrive. As each new value is received, the oldest value is overwritten. The average and number of outliers for the samples in the training window are determined. The number of outliers in the counting window is then determined using the new average value and the outlier threshold value that remains constant throughout the process. In different embodiments, the counting window can be part of the training window or separate from the training window.

Embodiments in which the training values are updated with each new sample will be referred to as dynamic counting embodiments. Dynamic counting embodiments have the advantage of compensating for a slowly changing training environment. Such embodiments place a higher computational workload on the data processing system.

The behavior of the Co(W,x), where x is the last sample number, is then used to construct a real time trigger. In the simplest case, the trigger is generated if Co(W,x) is greater than a threshold value. In more complex triggers, the shape of Co(W,x) is analyzed to determine if a trigger is to be generated. For example, if the real time trigger is set to trigger on a pulse of certain duration, Co(W,x) will be analyzed to determine if it displays a pulse of the desired duration. Since Co(W,x) is much less sensitive to noise in the signal, false triggers are significantly reduced.

In a second exemplary embodiment, the present invention is used to monitor test equipment to detect failures of the test equipment. Consider a production line in which manufactured parts are inspected to determine if the parts are defective. An apparatus that will be referred to as a tester makes a measurement on each part as it passes a station on the production line. The sequence of measurements can be treated as a data stream that can be analyzed by the present invention. The goal of the analysis is to detect failures in the tester rather than failures of the parts being tested by the tester. Assume that the tester measures a property of the part being inspected. The property could be a voltage presented on a particular terminal when the part is connected to various test signals. Good parts vary from one to another within some predetermined range with respect to this property, and hence, the data stream is subject to noise. The goal of the analysis performed by the present invention is to detect failures in the tester. The failure may be reflected in a gradual change in the measured property or periodic erratic measurements. For example, the tester could have a high rate of errors during certain periods of the day due to power fluctuations on the local grid. If the failure is a random event that results in the measured property being inaccurate, the failure may only be reflected in a part that fails that should not have failed. Detecting the tester failure may require a significant amount of time after the tester begins to fail, and hence, many good parts may appear to be defective, or worse, many bad parts may be passed. A tester failure that results in a small shift in the measured values can be seen as an event with the present invention.

As noted above, the data stream can be a binary data stream. An example of such a data stream is the output of a tester that simply provides a pass-fail determination for each part on the assembly line. The parts that pass can be represented by the value “0” and those that fail by the value “1”. An outlier is defined to be any value greater than 0. During the training phase, the statistical analysis determines the probability that any particular device fails when the tester is known to be working correctly. The counting function counts the number of failed devices in the counting window as a function of the number of devices tested less the expected number of failed devices. If the absolute value of the counting function as a function of the devices being tested differs significantly from zero, an event has occurred at a corresponding time on the production line. It should be noted that the event could correspond to too many devices being failed or too many devices being passed.

In the above examples, the data stream was scalar in nature. That is, the data stream consisted of one value at each time point in the data stream. However, the present invention can also be applied to a vector-valued data stream. In a vector-valued data stream, each time point has a plurality of measurements. Examples of instruments that generate such multi-value measurements at each time point include oscilloscopes with multiple measurement channels and circuit board testers that probe a circuit at a plurality of points while the circuit is stimulated with a predetermined set of test signals.

In principle, a vector-valued data stream can be treated as a plurality of individual measurements that are analyzed separately for events. However, if the measurement “channels” are not independent of each other, such an approach could miss events of interest. For example, cases in which all of the individual deviations were too small to trigger an outlier determination might actually trigger such a determination if the set of measurements were viewed as a whole. In addition, the event detection scheme would need to be repeated for each channel even in the case in which the channels are independent of one another.

The collection of measurements at each time point can be viewed as a vector having the measurements in question as its components. Consider a vector-valued data stream in which each vector has N components. The N components can be viewed as the coordinates of a point in an N-dimensional space. The noise in the measurements has the effect of converting what would be a single point in a non-noisy system to a cluster of points in the N-dimensional space. If the cluster is spherical in shape, the deviation of the individual measurements from the center of the cluster can be used to identify outliers. For example, if the center of the cluster is at a vector Vc, the deviation from the center by a vector V can be defined as the angle between Vc and V. This angle has a statistical distribution, and hence, an angle threshold can be defined that marks the boundary between an outlier and other vectors in the cluster. The methodology of the above analysis can then be applied to the angles for each new vector in the vector-valued data stream. That is, given a new vector in the vector-valued data stream, determine if it is an outlier. Count the number of outliers in the window W as a function of the position of the latest vector in the vector-valued data stream.

In the more general case, the cluster of vectors is not spherical. Even in systems in which each component has a normal statistical distribution, the standard deviations of the individual components around the mean of that component may vary from component to component. In this case, the surface that contains a predetermined fraction of the measurements would be expected to be an ellipsoid in the N-dimensional space. If, in addition, two or more of the components are correlated, one or more of the ellipsoid's axes will not be parallel to the axes in the N-dimensional space.

However, in general, there is a surface that contains any predetermined percentage of the points in the N-dimensional space. For example, if the surface is set to contain 90 percent of the vectors, then a point outside the surface has only a 1 in 10 chance of being part of the cluster. Hence, if a point is outside that surface, the point is an outlier. Accordingly, the system of the present invention needs to define a probability that defines the boundary and then compute the surface that contains that fraction of the vectors. The system can then count the outliers as before to determine the start of an event of interest.

The above-described embodiments require a training window that is assumed to be free of any “events” and can be analyzed statistically to arrive at a measure that will allow any subsequent point to be defined as an outlier if it violates that measure. The learning sample also needs to have some level of outliers. As will be discussed in more detail below, the learning sample could have a small number of outliers that are the result of an underlying event. In this case, the threshold for defining an outlier will be somewhat in error and the number of outliers within the counting window needed to detect an “event” will be higher than would have been the case if the learning sample was event free.

In one simplest example, it is assumed that the parameter being measured is a constant that is corrupted by noise whose statistical distribution is well represented by a Gaussian distribution. In this case, a sample is defined to be an outlier if the sample is more than some specified number of standard deviations from the mean. The learning sample must be sufficient to obtain a good approximation of the mean and standard deviation.

The counting window W slides along the sequence of measured values. In one aspect of the invention, the counting function is normalized for the size of the window and the expected number of outliers within the window if no event of interest is present. Denote the probability that any given sample is an outlier in the absence of any event of interest by p. The parameter p is determined by the statistical properties of the noise distribution and the cut-off used to define an outlier. In general, the user defines an outlier threshold value and defines an average measurement value. The manner in which the user defines the outlier threshold value and the average measurement will be discussed in more detail below. For example, if the measurements are scalar in nature, the average measurement values could be the average value for samples in the training window or the mean of the values in the training window. If a measurement differs from the average measurement value by more than the outlier threshold value, the measurement is defined to be an outlier. The probability that any given measurement is an outlier in the absence of an event is the number of outliers found in the training window divided by the number of samples in the training window.

The expected number of outliers in a window of size Nₛ samples is pNₛ. The simplest counting function is Co(W,x)=Nₒᵤₜ, the number of outliers in the window defined at sample x in the sequence of measurements. This function changes with the width of the window, and hence, the results with different window sizes are not easily compared. A better counting function that lacks this problem is given by

Co(W,x)=Nₒᵤₜ−pNₛ.

This counting function has the advantage of facilitating comparisons between the results for different choices of window size.

The placement of the sliding window at point xᵢ in the data stream depends on the speed with which the results are needed. If the window is placed around point i, the result will lag the data acquisition by Nₛ/2 samples. This delay may present problems in real time triggering applications. In such applications, it may be advantageous to use a window which includes the sequence of Nₛ measurements that terminates in xᵢ.

In one aspect of the invention, a sample xᵢ is defined to be part of an event, if the count function value for that sample is greater than a first threshold value that indicates that the probably of that count occurring due to statistical variations is less than a predetermined probability. In general, an event is expected to span more than one sample because of the width of the window used by the counting function. A single large sample value will increase the count for adjacent sample values that near the noise free average. If an event starts slowly with samples that are only marginally over expected noise, the counting function can display a rise time that does not cross the first threshold until well after the event has started. Hence, in one aspect of the invention, an xᵢ is assigned to an event even if the corresponding count is less than the first threshold if one of its neighbors was assigned to the event and the count function value for that sample is greater than a second threshold value that is lower than the first threshold value.

The above examples assume that the mean of the data stream is a constant between “events”. However, embodiments that take into account changes in the mean over time can also be constructed. In one embodiment, the measurement of the mean and standard deviation is performed just prior to each search for an event. This embodiment is adapted for real time trigger systems in which the signal being measured is connected to the test equipment just prior to the measurements.

In another embodiment, the calibration is performed at specific times of day. This embodiment is adapted for monitoring test equipment on a production line as discussed above. It is also useful in environments in which the noise changes with the time of day.

The above embodiments assume that the mean of the signal that is subject to the noise is constant. However, in some applications, the signal being monitored may have a known time dependency and the instrument is to be triggered by events that occur on top of that variation in the signal. For example, the user of an oscilloscope that is measuring a signal that includes a 60-cycle amplitude variation from the power lines may wish to capture transients that are imposed on the signal. In this case, the mean has a sinusoidal variation and outliers are judged relative to the underlying sinusoidal variation. During calibration, the mean must be fitted to a sine wave and the amplitude, phase, and frequency of the sine wave determined. The statistics of the noise about that sine wave are then used to define outliers. Within a counting window, the difference between the sine wave and the observed signal values is then compared to a cut-off to determine if a point is an outlier.

The above-described embodiments require a method for determining if a given sample is an outlier with respect to the statistics of the signal being measured. If there is a region of the data stream that is known to be free of events, that region can be used to measure the statistics of the signal and define the cut-off for determining if an individual signal value is an outlier. Unfortunately, being able to define such a region is not always possible. Typically, the system is presented with a sequence of measurements spanning a large window in which the smaller window used for counting outliers is moved along the last portion of the signal. If the large window is used to compute the statistics and the outlier cut-off, the cut-off may be skewed in a manner that results in the beginning of the event being missed.

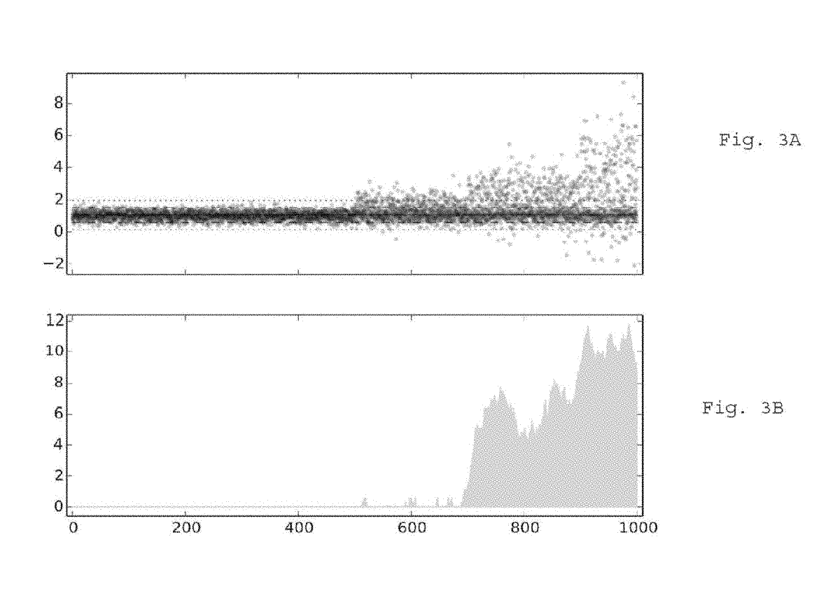

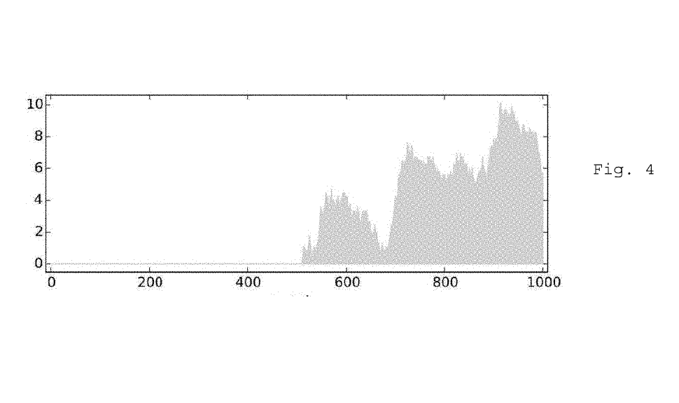

Refer now to FIGS. 3A-3B. FIG. 3A is a plot of a noisy data stream in which an event starts around sample 500. FIG. 3B is a plot of a counting function that counts the number of outliers in a window of size 151 samples. In this example, the entire signal shown in FIG. 3A is used to compute the statistics that determine whether a point is an outlier. Refer now to FIG. 4, which illustrates the counting function that is obtained if only the first quarter of the samples in FIG. 3A is used to compute the statistics on which the outlier cut-off is based. As can be seen, the counting function now clearly identifies the event starting at about sample 500.

Hence, it is advantageous to identify a region of the data stream in which no event occurs and which contains sufficient points to provide a good measure of the underlying noise statistics. One method for arriving at such a region is to use the entire sequence or at least a very large portion of that sequence to define a first approximation to an outlier cut-off. Using that outlier cut-off, a region of the data stream that has a count that is consistent with being event free can be identified. The outlier cut-off can then be re-computed using samples in that event free region for use in processing the entire data stream. The procedure can be iterated if necessary until a stable value for the cut-off threshold is obtained.

If the training window includes significant events, the counting function will be characterized by extended regions in which the counting function is negative. Including regions having events in the training function results in the estimate of p being too large, since the events have higher numbers of outliers and the training sample depends on the average number of outliers per sample.

While the above described embodiments relate to time series, any ordered series that can be sub-sampled into windows or bins is amenable to the counting analysis of the present invention. For example, frequency domain data such as spectra could be analyzed. Here the ordering is by frequency rather than time. A single spectrum could be analyzed to determine RF signals that have power values above the random RF noise. Or there might be some criteria for large transmission values that can be used to define expected power levels vs. outlier levels.

Generally, for any series it is also possible to transform the data into another domain such as first or second derivative, FFT, log transform, etc. before subjecting the series to the statistical analysis of the present invention. The transformed domain may provide a more convenient definition of outliers. For example, if a trigger were concerned with the rise time of input signals, the input signal could be transformed using a first derivative transform to accentuate the rise and fall times of the signal. While the transformed signal accentuates the signal property of interest, the signal also has significantly more noise, since the derivative transformation amplifies noise as well as the rise time of interest. The analysis of the present invention would then search for anomalous values in the first derivative space even in the presence of the enhanced noise.

The counting function can provide other information besides identifying the location of events. The area under the counting function is a measure of the size of the event. If the events occur on a regular schedule, the counting function can detect the relationship between the events and other parameters such as time of day. If the area or peak are increasing in time, the events are increasing in magnitude.

The above described embodiments depend on defining a cut-off value above which a sample is considered to be an outlier. In one aspect of the invention, the sample values are normalized to provide a normalized value, Zᵢ, corresponding to each sample xᵢ in the data stream, where

Zᵢ=(xᵢ−μ)/σ

Here, μ is the mean of the samples in the data stream and σ is the standard deviation of the series of values. The cut-off value Z_{c} is then a measure of the departure of the sample value from the mean in units of σ.

Rather than depending on the mean and standard deviation to normalize and classify points as outliers, other statistical measures can be utilized. For example, using the median and interquartile range (IQR) provides an analogous estimate of centrality and dispersion, but is less sensitive to large outliers that might skew the mean and variance. In one aspect of the invention, the median and IQR are substituted for their counterparts in the z-normalization, and a cutoff based on some multiple of IQRs from the median is utilized.

Another classification system used the median of the absolute deviation of the median, MAD, where

MAD=median{|xᵢ−xm|},

where xm is the sample median. A suitable normalization for sample x is

M(x)=0.6745(x−xm)/MAD

The factor 0.6745 is added to make the normalized values approximately comparable to the Gaussian z-score discussed above.

In the above described embodiments, a sample is part of an event if the counting function in the window corresponding to that sample is greater than some predetermined event threshold value. If the event threshold value is set too high, statistically significant events may be lost. If the event threshold value is too low, a significant number of false positives can be generated. In general, the optimum event threshold value will depend on the relative costs associated with false positives or missed events. However, it is advantageous to set the event threshold value in terms of the standard deviation of shot noise in the measurement. If the noise is Gaussian, and the count function value is greater than one standard deviation, the conclusion that an event has occurred will correct approximately 60 percent of the time. A similar conclusion can be advanced for higher multiples of the shot noise standard deviation. As noted above, the shot noise standard deviation is approximately \sqrt{(p*Nₛ)}, where p is the probably from the training sample. In one exemplary embodiment, the counting function is normalized to the standard deviation of the shot noise. That is, Co(W,x)=(Nₒᵤₜ−p*Nₛ)/\sqrt{(p*Nₛ)}. In this case, the event threshold value can be set to be a number that provides the desired degree of certainty that the event is an outlier. It should be noted that this counting function's values can be compared across different count window sizes.

The above-described embodiments also assume that the counting window remains constant in size with respect to the number of sample values in the counting window. In some applications, it may be advantageous to allow the size of the counting window to vary. For example, a counting window that is constant in time may be more useful in applications in which the rate of sample generation varies somewhat over a work shift or other time interval of interest. In such cases, the number of samples in the window are counted and the sample count is used as Nₛ.

In one aspect of the present invention, the hypergeometric score is used for counting the function. The hypergeometric score, z, is defined by

$$Z = \frac{{n}_{outlier} - {N}_{s} p}{\sqrt{{N}_{s} p ( 1 - p ) ( \frac{{N}_{total} - {N}_{s}}{{N}_{total} - 1} )}}$$

Here, nₒᵤₜₗᵢₑᵣ is the number of outliers observed in the current window of size Nₛ, p is the probability that any given sample is an outlier in the absence of an event, and Nₜₒₜₐₗ is the size of the training window. This counting function provides a more exact normalization for the standard deviation of the shot noise in cases in which the probability of being an outlier is not much less than one.

The above-described embodiments assume that the number of samples in the sliding window remain constant from point to point in the data stream. However, embodiments in which the sliding window is defined as a time window can also be constructed. In this case, the number of samples in the sliding window may change from point to point if the rate at which samples are generated is not constant in time. In such embodiments, the number of samples with the sliding time window is counted and the actual number of samples in the window is used in determining if an event has occurred.

The above-described embodiments of the present invention are based on the observation that an event can be detected by measuring a property of the statistical distribution of a stream of signal values during a training phase and then measuring the same property in a window that moves along the data stream to determine if the property has changed significantly from the training period. In the above examples, the statistical property was the number of outliers defined by an average value and a outlier threshold value. If the number of outliers has changed significantly, the invention concludes that the statistical distribution has changed significantly, and hence, an event has occurred that deserves attention. Embodiments that utilize other measures of the underlying statistical distribution can also be constructed.

In one exemplary embodiment, the average value and standard deviation of the data values in the training window are computed. A sliding window analogous to the counting window discussed above moves over the data stream. At each x value, the standard deviation of the values about the training average value within a window of size Nₛ is computed and compared to the standard deviation of the values in the training window. If the standard deviation deviates by more than an event threshold value, an event is said to have occurred.

Embodiments based on other measures of the underlying statistical distribution can also be constructed. For example, the average value of the absolute value of the difference between the sample values and the average sample value could be used.

The present invention can be practiced on any data processing system that is capable of performing the statistical computations described above and any transformation of the data series to a new form on which the statistical analysis is performed. In addition to general purpose computers and the like, the present invention can be incorporated into the data processors on measurement instruments or implemented in special purpose hardware such as field programmable gate arrays or other customized hardware.

The above-described embodiments of the present invention have been provided to illustrate various aspects of the invention. However, it is to be understood that different aspects of the present invention that are shown in different specific embodiments can be combined to provide other embodiments of the present invention. In addition, various modifications to the present invention will become apparent from the foregoing description and accompanying drawings. Accordingly, the present invention is to be limited solely by the scope of the following claims.

What is claimed is:

1. A method for operating a data processing system to detect an event in a data stream comprising an ordered sequence of digital values, xᵢ, for i=1 to N_{d}, said method comprising
causing said data processing system to determine a base value for a statistical parameter of said digital values within a training window;
for each xᵢ in a region of interest in said ordered sequence of digital values, causing said data processing system to determine a sliding value for said statistical parameter corresponding to that xᵢ by measuring said statistical parameter of said xᵢ within a sliding window containing said xᵢ and which is different for each xᵢ; and
comparing said sliding value to said base value for each xᵢ in said region of interest to determine if said xᵢ is part of an event.

2. The method of claim 1 wherein said data stream comprises a signal that is corrupted by noise characterized by a noise spectrum, said statistical parameter comprising a measure of said noise spectrum.

3. The method of claim 1 wherein said statistical parameter comprises a probability that one of said digital values will be an outlier.

4. The method of claim 1 wherein said statistical parameter comprises a standard deviation of said digital values.

5. The method of claim 1 wherein said training window includes said sliding window.

6. The method of claim 1 wherein said training window does not include said sliding window.

7. The method of claim 1 wherein said digital values are scalar values having only two states, digital values having one of said two states being defined as outliers.

8. The method of claim 1 wherein each of said digital values is a vector having a plurality of components.

9. The method of claim 1 wherein said training window comprises M samples immediately preceding said sliding window in said data stream, said training window being a least four times larger than said sliding window, said sliding window moving with said xᵢ.

10. An analyzer that measures a signal in a region of a potential event of interest, said analyzer comprising:
a port for receiving said signal and converting said signal to an ordered sequence of digital values, xᵢ, for i=1 to N_{d}, and
a trigger circuit that determines a sliding value for a statistical parameter for each of said xᵢ in said region based on a sliding window containing that xᵢ and moving with each xᵢ, said trigger circuit generating an event of interest signal if said sliding value is greater than a base value for said statistical parameter determined from an analysis of said xᵢ in a training window.

11. The trigger circuit of claim 10 wherein said signal is corrupted by noise characterized by a noise spectrum, said statistical parameter comprising a measure of said noise spectrum.

12. The trigger circuit of claim 10 wherein said statistical parameter comprises a probability that one of said digital values will be an outlier.

13. The trigger circuit of claim 10 wherein said statistical parameter comprises a standard deviation of said digital values within said sliding window.

14. The trigger circuit of claim 10 wherein said training window includes said sliding window.

15. A method operating a data processing system to monitor a testing system that makes a measurement on a series of devices under test for failures of said testing system, said method comprising:
generating an ordered digital sequence of digital values, xᵢ, for i=1 to N_{d}, from a measurement output of said testing system, said measurement output measuring a property of each device under test;
causing said data processing system to determine a base value for a statistical parameter of said digital values within a training window;
for each xᵢ in a region of interest in said ordered sequence of digital values, causing said data processing system to determine a sliding value for said statistical parameter corresponding to that xᵢ by measuring said statistical parameter of said xᵢ within a sliding window containing said xᵢ and which is different for each xᵢ; and
comparing said sliding value to said base value for each xᵢ in said region of interest to determine if said xᵢ is part of an event.

16. The method of claim 15 wherein said statistical parameter comprises a probability that one of said digital values will be an outlier.

17. The method of claim 16 wherein said digital values are scalar values having only two states, digital values having one of said two states being defined as outliers.
